(19) United States
(12) Patent Application Publication
(10) Pub. No.: US 2003/0071347 A1
(43) Pub. Date: Apr. 17, 2003

(54) Semiconductor chip packaging device and method of manufacturing the same

(76) Inventors: Hsueh-Te Wang, Tzuoying Chiu (TW); Meng-Jen Wang, Pingtung City (TW); Chun-Jen Tseng, Fengshan City (TW)

Correspondence Address: MARTINE & PENILLA, LLP, 710 LAKEWAY DRIVE, SUITE 170, SUNNYVALE, CA, 94085, US

(21) Appl. No.: 10/143,042

(22) Filed: May 9, 2002

(30) Foreign Application Priority Data
Oct. 17, 2001 (TW) 90125727

(51) Int. Cl. H01L 23/10

(52) U.S. Cl. 257/706

(57) ABSTRACT

A semiconductor chip packaging device including a semiconductor chip, a heat spreader and a metal layer. The heat spreader is provided above the semiconductor chip, and the metal layer is provided between the heat spreader and the semiconductor chip to bond the heat spreader and the semiconductor chip without using a heat conducting adhesive.

### BACKGROUND OF THE INVENTION

1. Field of the Invention

The invention relates to a semiconductor chip packaging device, in which the heat spreader is bonded to the semiconductor chip by a metal layer without using a heat conducting adhesive, and the method of manufacturing the semiconductor chip packaging device.

2. Related Art

The flip-chip bonding technique is different from the conventional way of establishing signal connections using bonding wires, in that a semiconductor chip is “flipped” so that its bonding surface provided with contacts faces a substrate. Then, conductors such as metal bumps or solder balls are used to electrically connect the contacts of the semiconductor chip and the contacts of the substrate. Due to the advantages of short bonding wires, low transmission delay, easy control of high frequency noise and small size of the packaging device, the flip-chip bonding technique has been extensively utilized in recent years.

As the integration of a semiconductor chip becomes higher and the size of a packaging device becomes smaller, the heat flux density of the packaging device becomes higher. To improve the heat dissipation rate of the packaging device effectively, engineers have developed many types of packaging devices. Referring to FIG. 1, an HFC-BGA (High performance Flip Chip Ball Grid Array) 1 includes a substrate 11, a semiconductor chip 12, a heat spreader 15 and a heat conducting adhesive 17. The semiconductor chip 12 is flipped so that the bonding surface of the semiconductor chip 12 faces the substrate 11, and the semiconductor chip 12 and the substrate 11 are electrically connected by solder balls 13. A stiffener ring 18 is provided on the substrate 11 to enhance the stiffness of the substrate 11. To reduce the stress concentration when the packaging device is subjected to force, spaces between the solder balls 13 and the semiconductor chip 12, and the solder balls 13 and the substrate 11 are filled with underfills 14.

Furthermore, to electrically connect the packaging device to a circuit board or other electronic devices, solder balls 19 are provided on another surface of the substrate 11, the surface of which is opposite the surface electrically connected to the semiconductor chip 12. The heat spreader 15 is attached to the semiconductor chip 12 by the heat conducting adhesive 17 to dissipate the heat generated by the semiconductor chip 12.

The packaging device 2 shown in FIG. 2 is a variation of the packaging device 1 shown in FIG. 1. The elements referred by the reference numerals 21, 23, 24, 25, 27 and 29 correspond to the elements referred by the reference numerals 11, 13, 14, 15, 17 and 19, respectively. Referring to FIG. 2, when the semiconductor chip 22 is larger, the stiffener ring 18 can be omitted. That is, the semiconductor chip 21 itself can enhance the stiffness of the substrate 21.

In the conventional packaging device shown in FIG. 1, the heat spreader 15 is bonded on the semiconductor chip 12 by the heat conducting adhesive 17. That is, the heat spreader 15 is attached on the semiconductor chip 12 implementing the DLA (Direct Lid Attach) technique. In the DLA technique, the space between the heat spreader 15 and the semiconductor chip 12 is called a BLT (Bond Line Thickness). If the BLT of the packaging device is too large, the heat conducting adhesive 17 will be too thick, which affects the heat dissipation efficiency of the packaging device. However, if the BLT of the packaging device is too small, the heat conducting adhesive 17 will be too thin to provide enough bonding strength between the heat spreader and the semiconductor chip.

Moreover, the heat conducting adhesive 17 must has a high bonding strength, which leads to increased costs.

Furthermore, according to the packaging device shown in FIG. 2, the heat spreader 25 is bonded to the semiconductor chip 22 directly by the heat conducting adhesive 27 without the support of the stiffener ring. Therefore, the heat spreader 25 tends to tilt, which results in the void generation and the delamination of the heat conducting adhesive 27, which reduces the heat dissipation efficiency of the packaging device.

### SUMMARY OF THE INVENTION

In view of the above issues, an object of the invention is to provide a semiconductor chip packaging device and its manufacturing method, in which the heat spreader and the semiconductor chip can be bonded tightly.

Another object of the invention is to provide a semiconductor chip packaging device and manufacturing method without using a heat conducting adhesive.

Still another object of the invention is to provide a semiconductor chip packaging device and its manufacturing method, in which the space between the heat spreader and the semiconductor chip can be minimized.

To achieve the above objects, the invention provides a semiconductor chip packaging device, which includes a substrate, a semiconductor chip, a heat spreader and a metal layer. The semiconductor chip is provided on, and is electrically connected to, the substrate, and the heat spreader is provided on the semiconductor chip. The metal layer is provided between the semiconductor chip and the heat spreader to bond the semiconductor chip and the heat spreader.

The metal layer may by plated to the heat spreader, and may be eutectically bonded to the semiconductor chip. The metal layer may include gold.

The semiconductor chip and the substrate may be electrically connected using the flip-chip bonding technique.

The invention also provides a method of manufacturing the semiconductor chip packaging device mentioned above, which coats the metal layer on a surface of the heat spreader, and bonds the metal layer to the semiconductor chip.

The bonding may be accomplished by heating the metal layer to the eutectic temperature of the metal constituting the metal layer and silicon. The metal constituting the metal layer may be gold, and the eutectic temperature may be about 370° C.

The coating may be accomplished by plating, depositing or sputtering.

According to the invention, instead of using a heat conducting adhesive, a metal layer, which can be very thin, is used to bond the heat spreader and the semiconductor device. Using this method can reduce costs.

According to the invention, since the metal layer is utilized to bond the heat spreader and the semiconductor device, the heat spreader and the semiconductor device can be bonded tightly.

According to the invention, the metal layer can be very thin. Therefore, the space between the heat spreader and the semiconductor chip can be minimized.

### BRIEF DESCRIPTION OF THE DRAWINGS

These and other features, aspects and advantages of the invention will become apparent by reference to the following description and accompanying drawings which are given by way of illustration only, and thus are not limitative of the invention, and wherein:

FIG. 1 is a schematic diagram showing an HFC-BGA type semiconductor chip packaging device in the prior art;

FIG. 2 is a schematic diagram showing a semiconductor chip packaging device having a heat spreader;

FIG. 3 is a schematic diagram showing the semiconductor chip packaging device according to a preferred embodiment of the invention; and

FIG. 4 is a flowchart showing the process of manufacturing the semiconductor chip packaging device according to the preferred embodiment of the invention.

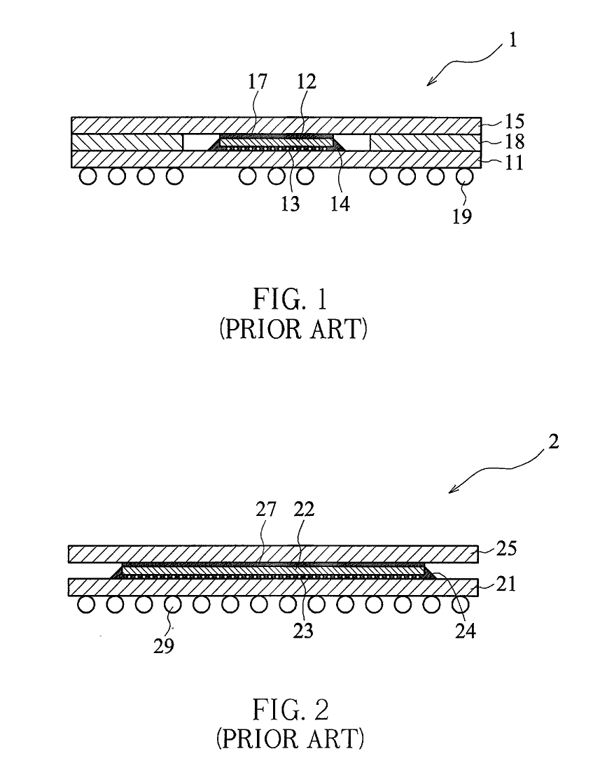

### DETAILED DESCRIPTION OF THE PREFERRED EMBODIMENT

The features, aspects and advantages of a preferred embodiment of the invention will be apparent from the following detailed description, which proceeds with reference to the accompanying drawings, wherein the same reference numerals relate to the same elements.

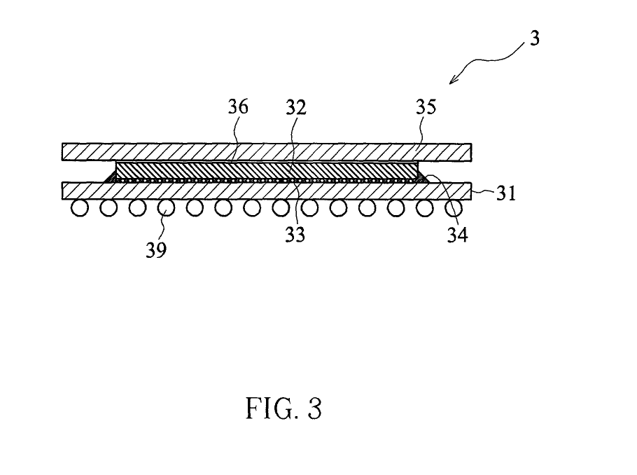

Referring to FIG. 3, the semiconductor chip packaging device 3 according to a preferred embodiment of the invention includes a substrate 31, a semiconductor chip 32, a heat spreader 35 and a metal layer 36. The semiconductor chip 31 is flipped so that its bonding surface faces the substrate 31. Solder balls 33 are used to electrically connect the contacts of the semiconductor chip 32 and the contacts of the substrate 31. To reduce the stress concentration when the semiconductor chip packaging device 3 is subjected to force, spaces between the solder balls 33 and the semiconductor chip 32, and between the solder balls 33 and the substrate 31 are filled with underfills 34.

In the preferred embodiment, the metal layer 36 is formed of gold, and is coated on the heat spreader 35 by sputtering, plating, depositing or other surface-coating technique. When raising the temperature to about 370° C., an Au—Si eutectic bonding phenomenon occurs at the interface of the gold in the metal layer 36 and the silicon in the semiconductor chip 32 to bond the heat spreader 35 and the semiconductor chip 32 tightly.

Moreover, to electrically connect the semiconductor chip packaging device 3 to a circuit board or other electronic devices, solder balls 38 are provided on another surface of the substrate 31, which surface is opposite to the surface electrically connected to the semiconductor chip 12.

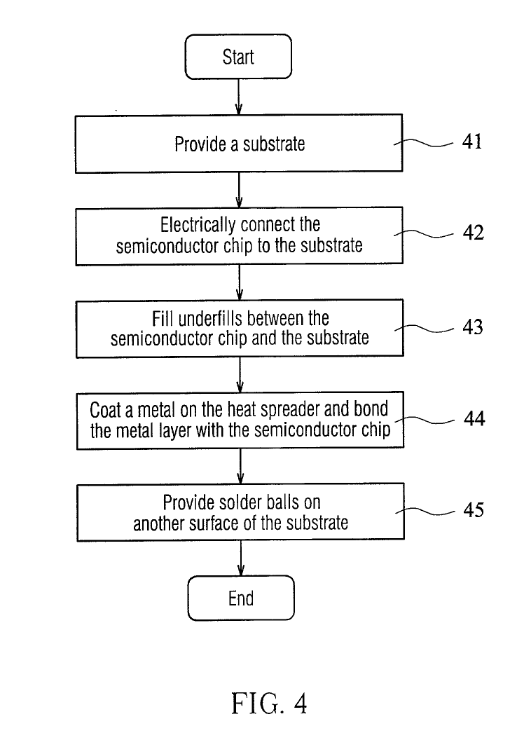

The method for manufacturing the above-mentioned semiconductor chip packaging device according to the preferred embodiment of the invention will be described below with reference to FIG. 4.

In step 41, a substrate is provided. The substrate may be a plastic substrate or a ceramic substrate. Then, in step 42, a semiconductor chip is electrically connected to the substrate. The semiconductor chip is flipped so that its bonding surface faces the substrate, and the solder balls mounted on the semiconductor chip are used to electrically connect the contacts of the semiconductor chip and the contacts of the substrate.

In step 43, underfills are filled between the semiconductor chip and the substrate to reduce the stress concentration when the semiconductor chip packaging device is subjected to force. More specifically, the underfills are filled between the solder balls and the semiconductor chip, and between the solder balls and the substrate.

In step 44, gold is coated on a heat spreader by sputtering, plating, depositing or other technique to from a metal layer consisting of gold. The metal layer is then heated to the eutectic temperature of gold and silicon, which results in the chemical reaction of eutectic bonding between the silicon in the semiconductor chip and the metal layer. The eutectic temperature of two materials is the lowest temperature at which a mix of the two materials will melt, and often is much lower than the melting temperatures of the two materials. For gold and silicon, the eutectic temperature is about 370° C.

In step 45, solder balls are provided on the surface of the substrate that is opposite to the surface electrically connected to the semiconductor chip. The solder balls are used to electrically connect the semiconductor chip packaging device to a circuit board or other electronic devices

Since the eutectic bonds have higher bonding strength than adhesives, they can bond the heat spreader and the semiconductor chip more tightly. Therefore, the heat spreader does not tend to tilt, and the problems of void generation and delamination of the heat conducting adhesive can also be avoided.

The metal layer can be very thin compared to the heat conducting adhesive. Therefore, the space between the heat spreader and the semiconductor chip can be minimized. The heat dissipation rate can be significantly improved.

Instead of using a heat conducting adhesive, the invention uses a metal layer, which can be very thin, to bond the heat spreader and the semiconductor device. This can reduce costs.

While the invention has been described with reference to a preferred embodiment, this description is not intended to be construed in a limiting sense. Various modifications of the embodiment will be apparent to persons skilled in the art upon reference to the description. It is therefore intended that the appended claims encompass any such modifications.

What is claimed is:

1. A semiconductor chip packaging device, comprising:
a semiconductor chip;
a heat spreader provided above the semiconductor chip; and
a metal layer provided between the semiconductor chip and the heat spreader to bond the semiconductor chip and the heat spreader.

2. The semiconductor chip packaging device according to claim 1, wherein the metal layer is eutectically bonded to the semiconductor chip.

3. The semiconductor chip packaging device according to claim 1, further comprising a substrate electrically connected with the semiconductor chip using the flip-chip bonding technique.

4. The semiconductor chip packaging device according to claim 1, wherein the metal layer comprises gold.

5. A semiconductor chip packaging device, comprising:
a substrate;
a semiconductor chip electrically connected to the substrate by the flip-chip bonding technique;
a heat spreader provided above the semiconductor chip; and
a metal layer plated on the heat spreader and eutectically bonded to the semiconductor chip.

6. The semiconductor chip packaging device according to claim 5, wherein the metal layer comprises gold.

7. A method of manufacturing a semiconductor chip packaging device, comprising:
coating a metal layer on the surface of a heat spreader; and
bonding the metal layer to the semiconductor chip.

8. The method according to claim 7, wherein the bonding comprises heating the metal layer to the eutectic temperature of the metal constituting the metal layer and silicon.

9. The method according to claim 7, wherein the metal constituting the metal layer is gold, and the eutectic temperature is about 370° C.

10. The method according to claim 7, wherein the coating is accomplished by plating.

11. The method according to claim 7, wherein the coating is accomplished by depositing.

12. The method according to claim 7, wherein the coating is accomplished by sputtering.
